(19) United States
(12) Patent Application Publication
(10) Pub. No.: US 2006/0024922 A1
(43) Pub. Date: Feb. 2, 2006

(54) Method for cutting wafer

(76) Inventors: Da-Tung Wen, Chupei City (TW); Da-Ming Wen, Chupei City (TW)

Correspondence Address: Keith Kline;PRO-TECHTOR INTERNATIONAL SERVICES, 20775 Norada Court, Saratoga, CA, 95070-3018, US

(21) Appl. No.: 10/900,674

(22) Filed: Jul. 27, 2004

(51) Int. Cl. H01L 21/78

(52) U.S. Cl. 438/462; 438/465

(57) ABSTRACT

A method for cutting wafer according to the invention includes a roller disposed below a pressing and grinding mechanism, and separates a piece of wafer into a plurality of small chips or dies by pressing and grinding scribe lines of the wafer, thereby optimizing efficiency of wafer cutting operations.

### BACKGROUND OF THE INVENTION

(a) Field of the Invention

The invention relates to a method for cutting wafer, and more particularly, to a method that separates a piece of wafer into a plurality of small chips or dies by pressing and grinding scribe lines of the wafer using a roller provided at a lower portion of a rolling mechanism, thereby optimizing efficiency of wafer cutting operations.

(b) Description of the Prior Art

Referring to FIG. 1 showing a prior method for cutting wafer, a piece of water 5 has a reverse side thereof attached with a film membrane 51, and then has a surface with the film membrane 51 patterned with scribe lines 52 using laser. The wafer 5 is sawed into a plurality of small chips or dies according to the scribe lines 52 using a cutting device. To be more precise, cutting methods of the prior cutting device complete sawing operations in longitudinal and lateral directions by aligning with the scribe lines 52 using a cutting blade.

The prior method for cutting the wafer 5 indeed accomplishes fundamental purposes of cutting; however, it is found that sawing operations in longitudinal and lateral directions by aligning with the scribe lines 52 using a cutting blade are rather time consuming. The aforesaid issue can be solved by replacing a single cutting blade with a plurality of cutting blades that perform simultaneous sawing operations to optimize production efficiency. Yet, during sawing operations, supposed that slight errors or deviations take place when aligning the cutting blades with the scribe lines 52, it is much likely that significant amounts of defectives may be incurred.

### SUMMARY OF THE INVENTION

The primary object of the invention is to provide a method for cutting wafer, in that the method, unlike the prior method for cutting wafer using a cutting blade, separates a piece of wafer into a plurality of small chips using grinding and pressing means, thereby elevating cutting efficiency as well as lowering production time and costs.

### BRIEF DESCRIPTION OF THE DRAWINGS

FIG. 1 shows a schematic view illustrating a common piece of wafer to be cut.

FIG. 2 shows a flow chart according to the invention.

FIG. 3 shows an elevational view according to the invention.

FIG. 4 shows a schematic according to the invention before cutting operation.

FIG. 5 shows a schematic according to the invention in cutting operation.

FIG. 6 shows a partial schematic according to the invention in cutting operation.

FIG. 7 shows a flow chart of an embodiment according to the invention.

### DETAILED DESCRIPTION OF THE PREFERRED EMBODIMENTS

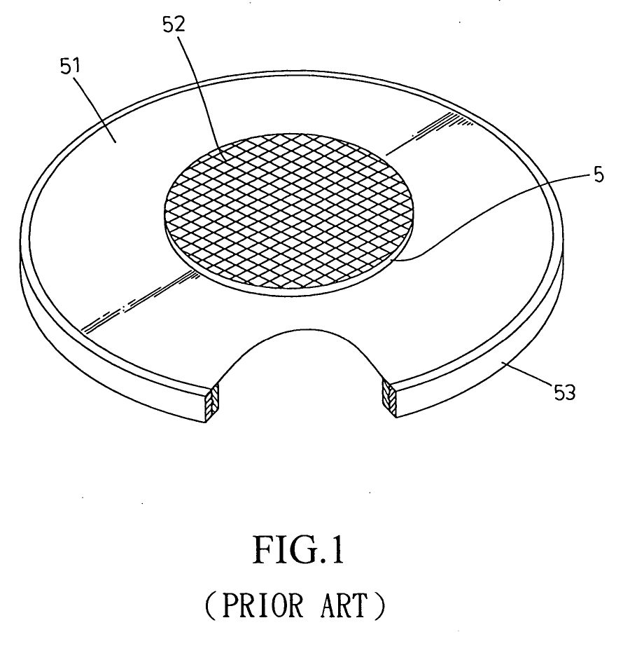

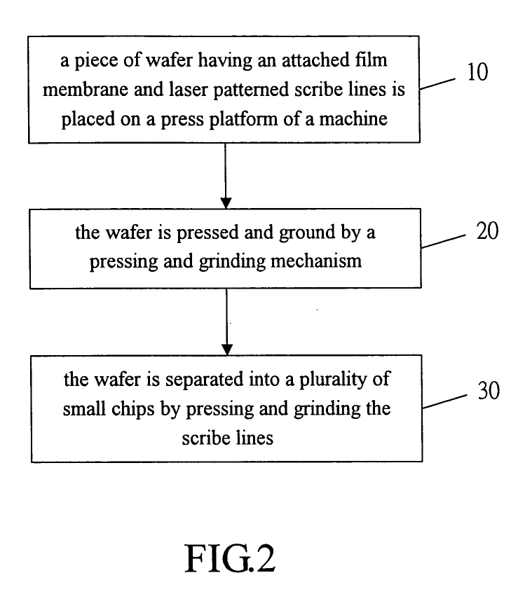

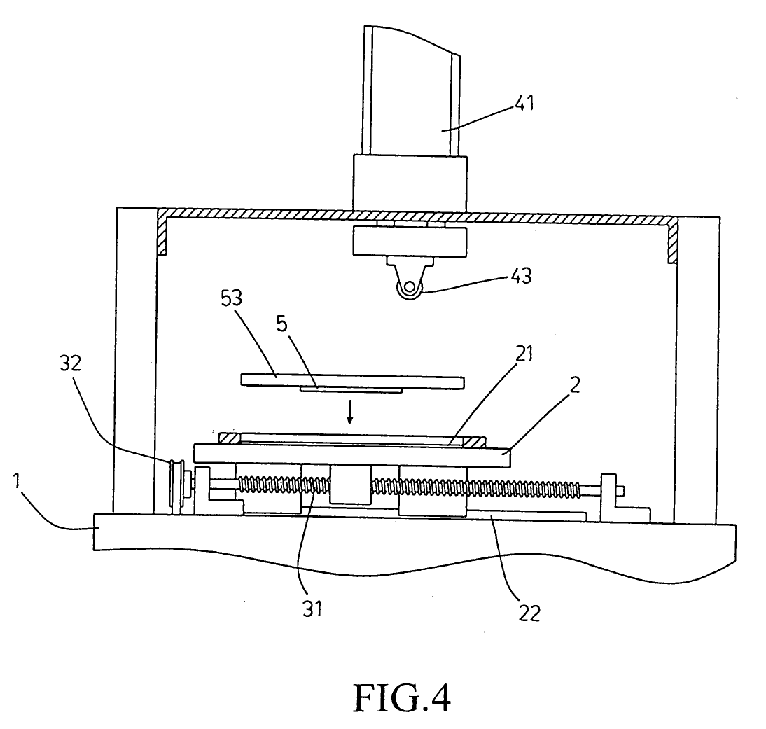

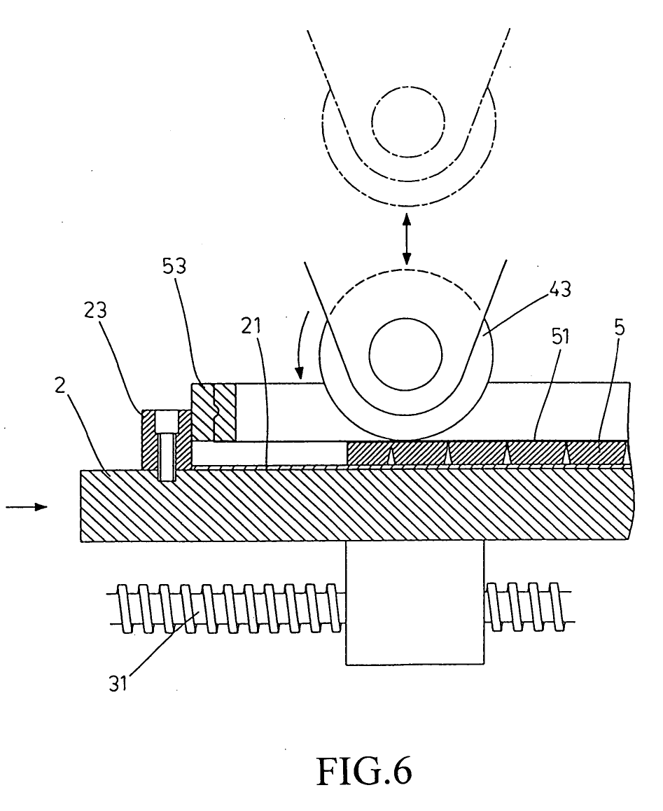

Referring to FIGS. 1 to 3, a method for cutting wafer according to the invention comprises steps of:
a step 10, wherein a piece of wafer 5 having an attached film membrane 51 and laser patterned scribe lines 52 is placed on a plastic pad 21 of a press platform 2 of a machine 1, with a surface of the wafer 5 having the film membrane 51 facing upward as shown in FIG. 4;
a step 20, wherein, using operations of a control panel 11 of the machine 1, the wafer 5 is pressed and ground by a pressing and grinding mechanism 4, with sections at the scribe lines 52 at the wafer 5 disengaged by pressure of the aforesaid roller 43 produced upon the wafer 5 as shown in FIG. 6; and
a step 30, wherein the wafer 5 is separated into a plurality of small chips by pressing and grinding the scribe lines 52.

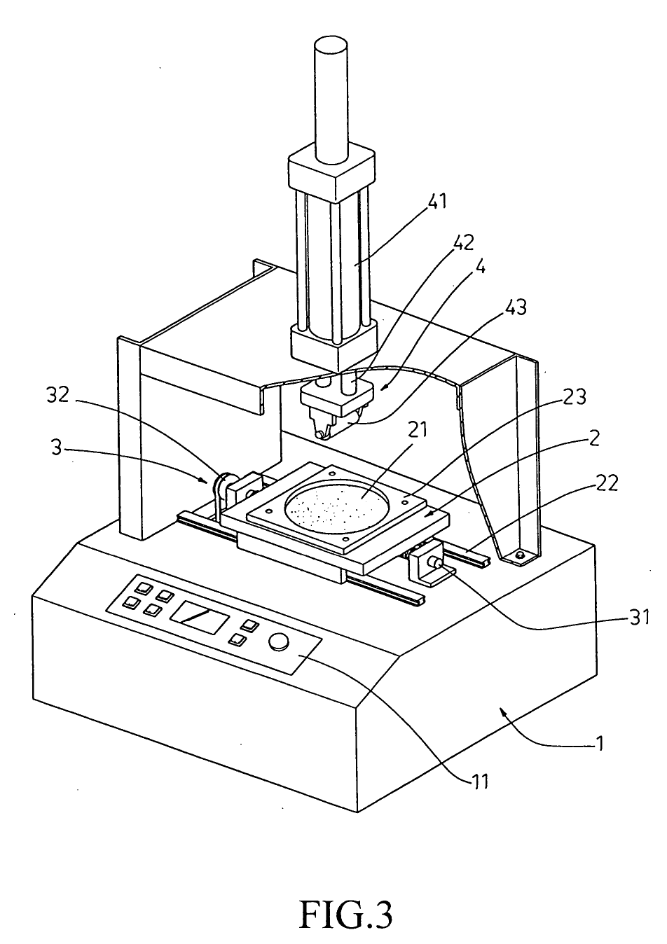

Referring to FIG. 3, with aid of a bearing, the press platform 2 is disposed on guiding tracks 22 at an operating surface of the machine 1. A driving device 3 is provided below the press platform 2, and is for performing and controlling back and forth sliding movements of the press platform 2 using a roller screw 31 driven by a transmission wheel 32. When the wafer 5 is displaced along with the press platform 2, the scribe lines 52 are pressed and ground, thereby separating the wafer 5 into a plurality of small chips.

According to the invention, the pressing and grinding mechanism 4 has a pressure valve 41 that pivotally disposes pistons 42 thereof downward in order to lower the roller 43; or the pressing and grinding mechanism 4 may lower the roller 43 using a server motor or a step motor.

According to the invention, the roller 43 of the pressing and grinding mechanism 4 may stay immobile. Instead, the press platform 2 is lifted toward the roller 43 using the driving device 3 till the to-be-cut wafer 5 on the press platform 2 is completely passed through the roller 43. In addition, a locating frame 23 at an upper surface of the press platform 2 is for placing and locating a film membrane locating frame 53 of the wafer 5 as shown in FIG. 1, so that the to-be-cut wafer 5 is facilitated to be readily placed and located within a pressing and grinding range of the roller 43.

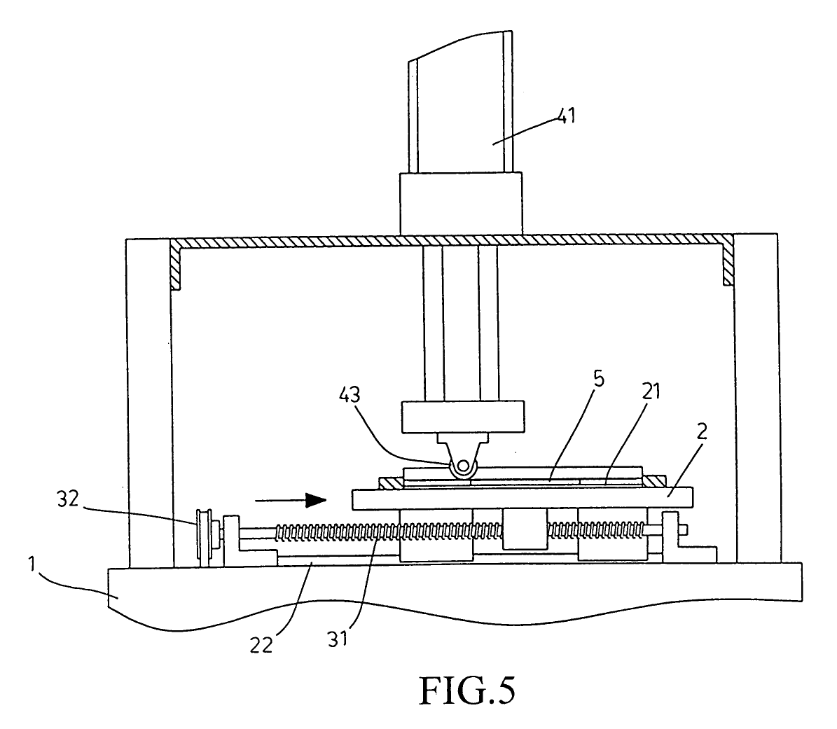

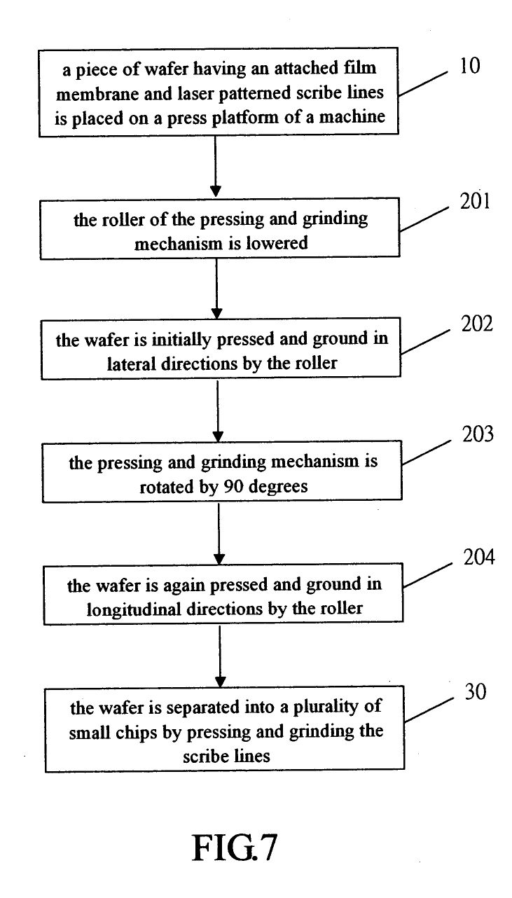

Referring to FIG. 7, a method for cutting wafer in another embodiment according to the invention comprises steps of:
a step 10, wherein a piece of wafer 5 having an attached film membrane 51 and laser patterned scribe lines 52 is placed on a plastic pad 21 of a press platform 20 of a machine 1, with a surface of the wafer 5 having the film membrane 51 facing upward as shown in FIG. 4;
a step 201, wherein, using operations of the control panel 11 of the machine 1, the roller 43 of the pressing and grinding mechanism 4 is lowered as shown in FIG. 5; a step 202, wherein the wafer 5 is initially pressed and ground in lateral directions by the roller 202; and a step 203, wherein the pressing and grinding mechanism 4 is rotated by 90 degrees, or the pressing platform 2 is rotated by 90 degrees instead of rotating the pressing and grinding mechanism 4; and a step 204, wherein the wafer 5 is again pressed and ground in longitudinal directions by the roller 43; and
a step 30, wherein the wafer 5 is separated into a plurality of small chips by pressing and grinding the scribe lines 52.

Conclusive from the aforesaid descriptions, the method for cutting wafer according to the invention is capable of cutting a piece of wafer into a plurality of small chips or dies, thereby significantly elevating efficiency of prior methods for cutting wafer.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. A method for cutting wafer comprising steps of:
a) placing a piece of wafer having an attached film membrane and laser patterned scribe lines on a press platform of a machine;
b) pressing and grinding the wafer using a pressing and grinding mechanism; and
c) separating the wafer into a plurality of small chips by pressing and grinding the scribe lines.

2. The method for cutting wafer in accordance with claim 1, wherein the pressing and grinding mechanism uses a roller for pressing and grinding the wafer.

3. The method for cutting wafer in accordance with claim 1, wherein the pressing and grinding mechanism lowers the roller using a pressure valve.

4. The method for cutting wafer in accordance with claim 1, wherein the pressing and grinding mechanism lowers the roller using a server motor.

5. The method for cutting wafer in accordance with claim 1, wherein the pressing and grinding mechanism lowers the roller using a step motor.

6. The method for cutting wafer in accordance with claim 1, wherein the wafer is placed on a plastic pad of the press platform with a surface thereof having a film membrane facing upward.

7. The method for cutting wafer in accordance with claim 1, wherein pressure produced by the roller of the pressing and grinding mechanism is sufficient for disengaging the scribe lines of the wafer.

8. The method for cutting wafer in accordance with claim 1, wherein the roller of the pressing and grinding mechanism presses and grinds the wafer in lateral directions.

9. The method for cutting wafer in accordance with claim 1, wherein the roller of the pressing and grinding mechanism presses and grinds the wafer in longitudinal directions.

10. The method for cutting wafer in accordance with claim 1, wherein an upper surface of the press platform has a locating frame for placing and locating a piece of to-be-cut wafer.

11. The method for cutting wafer in accordance with claim 1, wherein the press platform is disposed on guiding tracks at an operating surface of the machine with aid of a bearing.

12. The method for cutting wafer in accordance with claim 1, wherein a driving device is provided below the press platform, and is for displacing the press platform.

13. The method for cutting wafer in accordance with claim 12, wherein a driving device is provided below the press platform, and is for performing and controlling back and forth sliding movements of the press platform using a roller screw driven by a transmission wheel.

14. The method for cutting wafer in accordance with claim 12, wherein the driving device lifts the press platform for enabling the roller of the pressing and grinding mechanism to press and grind the wafer.
